(19) United States
(12) Patent Application Publication
(10) Pub. No.: US 2006/0115937 A1
(43) Pub. Date: Jun. 1, 2006

(54) Devices for an insulated dielectric interface between high-k material and silicon

(76) Inventors: Joel M. Barnett, Austin, TX (US); Mark I. Gardner, Cedar Creek, TX (US); Naim Moumen, Austin, TX (US); Jim Gutt, Chandler, AZ (US)

Correspondence Address: FULBRIGHT & JAWORSKI L.L.P., 600 CONGRESS AVE., SUITE 2400, AUSTIN, TX, 78701, US

(21) Appl. No.: 11/324,934

(22) Filed: Jan. 4, 2006

Related U.S. Application Data
(62) Division of application No. 10/911,981, filed on Aug. 5, 2004.
(60) Provisional application No. 60/498,676, filed on Aug. 28, 2003.

(51) Int. Cl. H01L 21/84; H01L 21/31; H01L 21/302

(52) U.S. Cl. 438/151; 438/787; 438/723

(57) ABSTRACT

Methods and devices are described for an insulated dielectric interface between a high-k material and silicon for improving electrical characteristics of devices. A method includes forming an oxide layer on a silicon substrate using an in situ steam generation process, etching the oxide layer to form a reduced thickness oxide layer of less than 10 Angstroms, and annealing the reduced thickness oxide layer with ammonia. A semiconductor wafer comprises a silicon substrate, an oxide layer coupled to the silicon substrate where the oxide layer having a thickness of less than 10 Angstroms, and a high-k dielectric material deposited onto the oxide layer.

This patent application claims priority to, and incorporates by reference in its entirety, U.S. provisional patent application Ser. No. 60/498,676 filed on Aug. 28, 2003, entitled, “A Method for Forming an Insulated Dielectric Interface Between High-K Material and Silicon.”

### BACKGROUND OF THE INVENTION

1. Field of the Invention

The present invention relates generally to semiconductor devices. More particularly, it concerns formation of a thin insulator dielectric interface between high-k material and silicon on a semiconductor device.

2. Description of Related Art

As research and development of dielectric materials advances, especially materials where the dielectric constant, k, is greater than 3.9, an insulator dielectric interface layer between a high-k film and a silicon substrate has proven beneficial. For example, the insulator dielectric interface layer may improve device electrical characteristics including leaking current density, mobility, transconductance and the saturated current.

Previous technologies have focused on using a chemical oxide grown by an ozonated water rinse process or a standard RCA type clean to create an insulator dielectric interface layer to fabricate an oxide film. However, the resultant film is too thick, approximately 1.0 nm, for practical implementation and thus, does not permit device scaling below 1 nm. In addition, the oxide continues to grow if subsequent heat treatment cycles are applied.

These shortcoming of conventional methods are not intended to be exhaustive, but rather are among many that tend to impair the effectiveness of previously known techniques concerning fabrication and scaling of a dielectric layer; however, those mentioned here are sufficient to demonstrate that methodology appearing in the art have not been altogether satisfactory and that a significant need exists for the techniques described and claimed in this disclosure.

### SUMMARY OF THE INVENTION

A thin insulator dielectric interface made and used according to the present disclosure may be designed to overcome limitations discussed above because the overall thickness of the layer may be controlled by etch back using wet chemical or dry etch processes.

According to aspects of the invention, a method for fabricating a semiconductor device on a silicon substrate, comprises forming an oxide layer using an in situ steam generation process on the silicon substrate, etching the oxide layer to form a reduced thickness oxide layer of approximately less than 10 Angstroms, and annealing the reduced thickness oxide layer in the presence of ammonia.

According to another aspect of the invention, a method comprises: forming an oxide layer on a silicon substrate using an in situ steam generation process, etching the oxide layer to form a reduce thickness oxide layer of approximately less than 10 Angstroms, annealing the reduced thickness oxide layer, and depositing a high-k dielectric material on the reduced thickness oxide layer.

According to yet another aspect of the invention, a semiconductor wafer is disclosed. The semiconductor wafer includes a silicon substrate, an oxide layer coupled to the silicon substrate, where the oxide layer is formed from an in situ steam generation process and etched back to a thickness of approximately 10 Angstroms, and a high-k dielectric material deposited on the oxide layer.

Further, the invention includes a semiconductor wafer which includes a silicon substrate, an oxide layer coupled to the silicon substrate, where the oxide layer is formed from an in situ steam generation process and etched back to a thickness of approximately 4 Angstroms, and a high-k dielectric material deposited on the oxide layer.

These, and other, embodiments of the invention will be better appreciated and understood when considered in conjunction with the following description and the accompanying drawings. It should be understood, however, that the following description, while indicating various embodiments of the invention and numerous specific details thereof, is given by way of illustration and not of limitation. Many substitutions, modifications, additions and/or rearrangements may be made within the scope of the invention without departing from the spirit thereof, and the invention includes all such substitutions, modifications, additions and/or rearrangements.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore nonlimiting, embodiments illustrated in the drawings, wherein like reference numerals (if they occur in more than one view) designate the same or similar elements. The invention may be better understood by reference to one or more of these drawings in combination with the description presented herein. It should be noted that the features illustrated in the drawings are not necessarily drawn to scale.

FIGS. 1-4 illustrate method steps in accordance with an embodiment of the present invention.

FIG. 5 is a semiconductor device in accordance with an embodiment of the present invention.

FIGS. 6A-6C are tables of different wafers and the electrical test results for each wafer in accordance with embodiments of the present invention.

FIG. 7 is a graph comparing equivalent oxide thickness and starting interface thickness in accordance to embodiments of the present invention.

FIG. 8 is a graph comparing post-etching processes contributions to equivalent oxide thickness and starting interface thickness in accordance to embodiments of the present invention.

FIG. 9 is a graph comparing equivalent oxide thicknesses and leakage current densities of embodiments of the present invention.

FIG. 10 is a graph comparing equivalent oxide thicknesses and voltages of embodiments of the present invention.

FIG. 11 is a graph comparing transconductance and inverse equivalent oxide thickness of embodiments of the present invention.

FIG. 12 is a graph comparing saturation current and equivalent oxide thickness of embodiments of the present invention.

FIG. 13 is a graph of threshold voltages of embodiments of the present invention.

FIG. 14 are mobility models of wafers fabricated from embodiments of the present invention.

FIG. 15 are mobility curves of wafers from embodiments of the present invention.

FIG. 16 is a graph comparing mobility of wafers and the starting interface thickness of embodiments of the present invention.

### DESCRIPTION OF ILLUSTRATIVE EMBODIMENTS

The invention and the various features and advantageous details thereof are explained more fully with reference to the non-limiting embodiments that are illustrated in the accompanying drawings and detailed in the following description. It should be understood that the detailed description and the specific examples, while indicating specific embodiments of the invention, are given by way of illustration only and not by way of limitation. Various substitutions, modifications, additions, and/or rearrangements within the spirit and/or scope of the underlying inventive concept will become apparent to those of ordinary skill in the art from this disclosure.

The invention sets forth methods and devices for a thick insulator dielectric at an interface and reducing the thickness by a controlled etch back. In particular, the invention is directed toward scaling down the equivalent oxide thickness and applying a NH₃ anneal process prior to the deposition of a high-k dielectric film, in which k may be greater than 3.9. This prevents further oxide growth in subsequent fabrication steps and reduces the equivalent oxide thickness. The equivalent oxide thickness (“EOT”), as described herein, relates to the performance of a metal on silicon (MOS) gate dielectric, where the dielectric constant, k, is about 3.9, and where the MOS gate may include a high-k material. The treated oxide layer has been found to be beneficial in improving device electrical characteristics, including leakage current density, mobility, transconductance and saturated current, Idₛₐₜ.

The formation of an oxide layer on a silicon substrate is well known in the art. The exposure of silicon to oxygen forms a silicon dioxide layer that becomes an electrical insulator as well as a barrier material during impurity depositions. For example, thermal oxidation is a method for growing an oxide layer, in which the wafer is heated to a high temperature ranging from 900° to 1200° C. in an atmosphere containing pure oxygen or water vapor. Another method of forming an oxide layer is during a wet cleaning and rinsing operation, known in the art as chemical oxide. During the cleaning of a wafer, a chemical oxide layer may be formed when a formula, such as the HF/HCl—O₃/HCl sequence with ozonated water, is dispensed onto the wafer. Yet another method of forming an oxide layer is known as steam oxidation. Water vapors of deionized water produced by vaporization is directed towards a wafer, causing oxidation on the silicon substrate.

In accordance to embodiments of the invention, a chemical oxide layer may be formed on a silicon wafer using the HF/HCl—O₃/HCl sequence with ozonated water. The HF/HCl etch process portions may follow and may include using a DI:HF:HCl process. Upon forming the oxide layer, an etching process may follow, where the etch time may be determined equivalent to the time needed to remove a certain amount of oxide. Following the etching process, the wafer may be subjected to an O₃ and an HCl rinse. For example, a 200:1:0.4 DI:HF:HCl formula at approximately 23° C. may be used to form a oxide layer upon a silicon wafer. An etch time can be determined such that the removal approximately 200 Å of oxide may be completed. Once the etching process is complete, O₃ is dispensed onto the wafer for a predetermined time, temperature, and concentration, for example, 10 min at 23° C. with an O₃ concentration of 20 parts per million (“ppm”) and an HCl concentration of 0.2%. The wafer may subsequently transferred to a low particulate dryer, LPD, where the wafer receives a 3-minute deionized water (DI) rinse and a low pressure isopropyl alcohol/hot N₂ dry.

Alternatively, in other embodiments, a chemical oxide layer is formed on a silicon wafer using an RCA-type cleaning method which may include a HF/HCl-SC1-SC2 sequence. The HF/HCl etch portion such as a 200:1:0.4 DI:HF:HCl formula at 23° C. may be dispensed and targeted to remove a thickness of the oxide. SC1 may be dispensed onto the wafer at a particular temperature and duration, e.g., 23° C. for 7 minutes, with a H₂O:H₂O₂:NH₄OH mixture with the ratio of 100:2:1, respectively. Finally, SC2 may be dispensed onto the wafer at a predetermined temperature and duration, e.g., 23° C. for 7 minutes with a H₂O:H₂O₂:HCl mixture of 50:1:1, respectively. After the SC2 rinse, the wafers may be transferred to the LPD where they received a 3-minute DI water rinse and a low pressure isopropyl alcohol/hot N₂ dry.

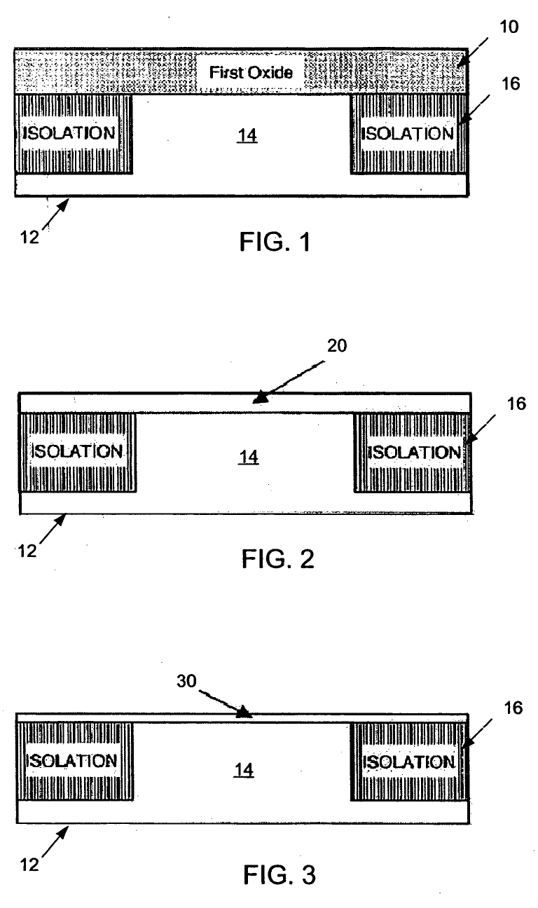

According to embodiments of the invention, an in situ steam generation (ISSG) oxide layer may be formed. A plurality of transistor wafers may first be cleaned using a sequence such as an HF/HCl—O₃/HCl sequence with ozonated water dispensed onto the wafer. Referring to FIG. 1, oxide layer 10 is formed at the interface of silicon substrate 12 resulting from the cleaning and rinsing process. It is noted that silicon substrate 12 may have undergone previous fabrication processes well-known in the art to define device region 14 surrounded by isolation regions 16. The wafers may then receive a 21 Å ISSG process on a rapid thermal processor (RTP), which includes a 16 second exposure to 4950 standard centimeter cube per minute (sccm) of O₂ and 50 sccm of H₂ at 950° C. and 5.8 Torr. The wafers may be processed again through the cleaning tool using the LPD process to reduce the oxide thickness from 21 Å. For example, an HF/HCl etch portion of the process using a 200:1:0.4 DI:HF:HCl formula at 23° C.; in which the etch times were varied to target approximately 10 Å of remaining ISSG oxide on some of the plurality of wafers and approximately 7 Å for others. Referring to FIGS. 1 and 2, oxide layer 20, compared to oxide layer 10 is substantially thinner.

The ISSG oxide may undergo an alternative etching process. After the rapid thermal processing, the wafers may be exposed to an anhydrous HF vapor process. The rinse-etch-rinse process using the anhydrous HF and water vapor targets to reduce the thickness of the oxide. Prior to the vapor etch, a 5-second water rinse may be employed to leave a uniform, adsorbed layer of moisture for better etch uniformity. After the vapor etch, a 7 second water rinse can be employed to remove the etch residues. Such a method may be directed to an oxide thickness of less than 4 Å, and preferably a wafer with approximately 3.7 Å partially hydrophobic, partially fluorine-terminated film on the silicon substrate 12.

For each embodiment described above, the wafers undergo an ammonia (NH₃) anneal process at 700° C. and 30 Torr for 15 seconds prior to the deposition of a high-k material. The anneal process, in conjunction with the scaling of the oxide interfaces, achieves thinner EOTs with acceptable electrical performances. Referring to FIG. 3, annealed oxide layer 30 is the result of an etching step (e.g., chemical etch, vapor etch, etc.) and the annealing process. Annealed oxide layer 30 may be less than or equal to approximately 10 Å. More precisely, oxide layer 30 may be less than or equal to approximately 4 Å. Even more precisely, oxide layer 30 may be less than or equal to approximately 3.7 Å.

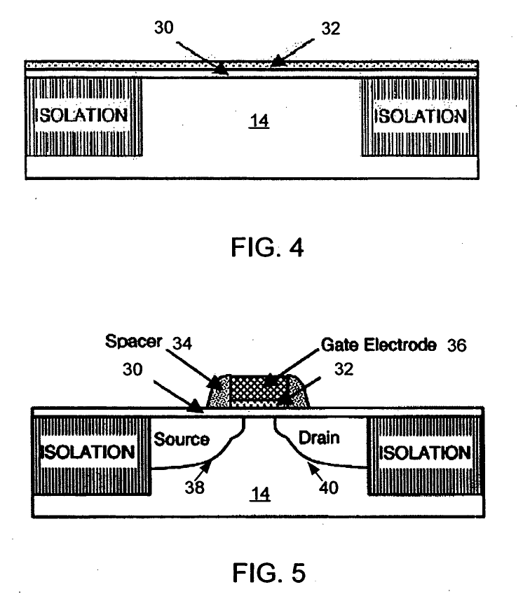

Referring to FIG. 4, following the annealing process, a high-k dielectric material 32 may be deposited on annealed oxide layer 30. The high-k dielectric material may be ZrO₂, Zr silicate, ZrSiON, Hf silicate, HfO₂, HfSiON, HfON, Hf-Aluminates, AlZrO₂, AlZrSiO₂, AlHfSiO₂, Al₂O₃, La2O₃, La silicate, Y₂O₃, Y silicate, LaAlO₃, Gd₂O₃, Gd silicate, Pr₃O₂, Pr silicate, or any of their hybrid combinations including nitrogen bearing high-k films. In one embodiment, the high-k dielectric material is HfSiₓO_{y} film of approximately 45 Å deposited on annealed oxide layer 30. Following the high-k dielectric material deposition, a post high-k ammonia anneal process may be performed at 700° C. and 30 Torr for 60 seconds.

Subsequent fabrication steps known in the art are subsequently performed to form a transistor as shown, for example, in FIG. 5. Such steps are well known in the art, which may include, gate oxide deposition, impurity deposition, source/drain implantation, source/drain diffusion, contact openings, metal deposition, etc. For example, a metal oxide semiconductor field effect transistor (MOSFET) transistor (e.g., an PMOS or an NMOS transistor) may be form and may include spacer 34, gate electrode, 36, source 38, and drain 40. After the formation of a transistor, the electrical characteristics of the transistor may be tested.

### EXAMPLES

The following example is included to demonstrate specific embodiments of this disclosure. Particularly, the examples below summarizes testing done to evaluate oxide interfaces created from various pre-gate wafer cleans and to determine the impact of subsequent NH₃ pre-high-k dielectric film deposition anneals on electrical performances. It should be appreciated by those of skill in the art that the techniques disclosed in the examples that follow represent techniques discovered by the inventors to function well in the practice of the invention, and thus can be considered to constitute specific modes for its practice. However, those of skill in the art should, in light of the present disclosure, appreciate that many changes can be made in the specific embodiments which are disclosed and still obtain a like or similar result without departing from the spirit and scope of the invention.

The example illustrates five different interfaces such as chemical oxides and ISSG thermal oxides and the effects of the respective oxide layer on electrical properties of the devices. Particularly, the example illustrates that an ISSG interface is more robust than a chemical oxide of equivalent thickness. Further, the example illustrates the results of a monolayer of partially fluorine-terminated ISSG oxide remaining after the anhydrous HF process.

Column 1 of Table 1 and 2 below includes the type of chemicals or process steps that a wafer is subjected to. Each step is done for an approximate period of time in seconds. For example, a process step includes subjecting a wafer to de-ionized water (DIW). Similarly, DIW-1 is subjecting a wafer to a high-flow of de-ionized water. H-DIW is subjecting a wafer to hot de-ionized water. Other process steps include moistening or showering (SH) the wafer, a quick dump rinse (QDR), and a dip time (DIP). Chemical process includes subjecting the wafer to different compound including ozone (O₃), ammonium hydroxide (NH₄OH), hydrogen peroxide (H₂O₂), hydrofluoric acid (HF), hydrochloric acid at a low rate (HCL-1), and/or hydrochloric acid at a high rate (HCL-2).

Further, Table 1 and 2 also include the time interval where a wafer is subjected to a megasonic power source (DSM). In some embodiments, a wafer may be subjected to a power setting (DSM-PW) corresponding to a level (e.g., 1-7). Each level has a predetermined power level. For example a “6” may indicate a power source of approximately 420 MHz.

A. Oxide Formation

1. A Chemical Oxide Formed by an IMEC-Type Clean Using an HF/HCl—O₃/HCl Sequence with an Ozonated Water Dispense

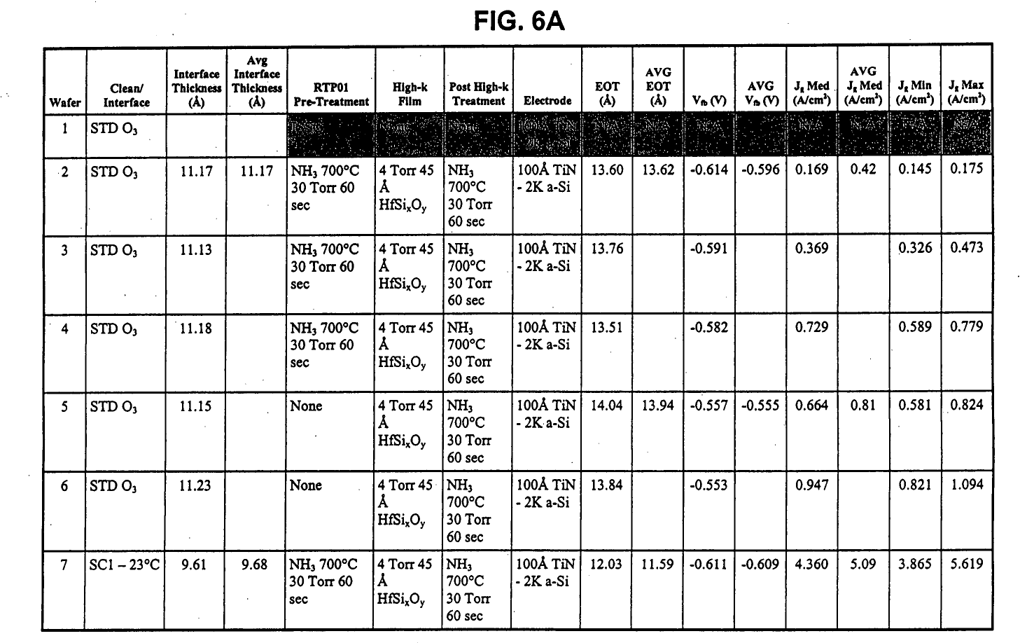

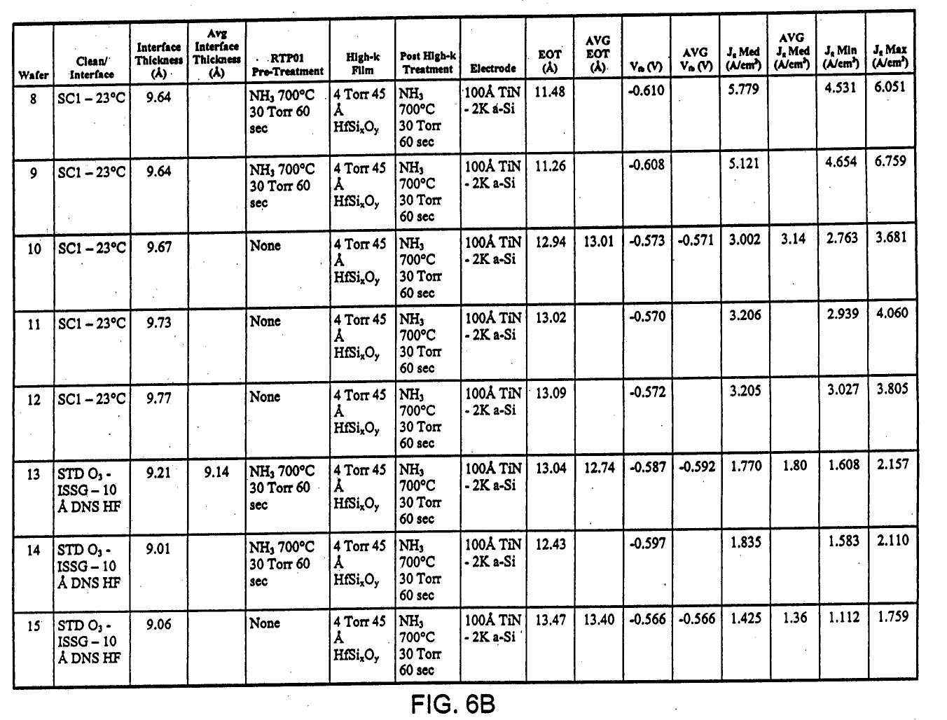

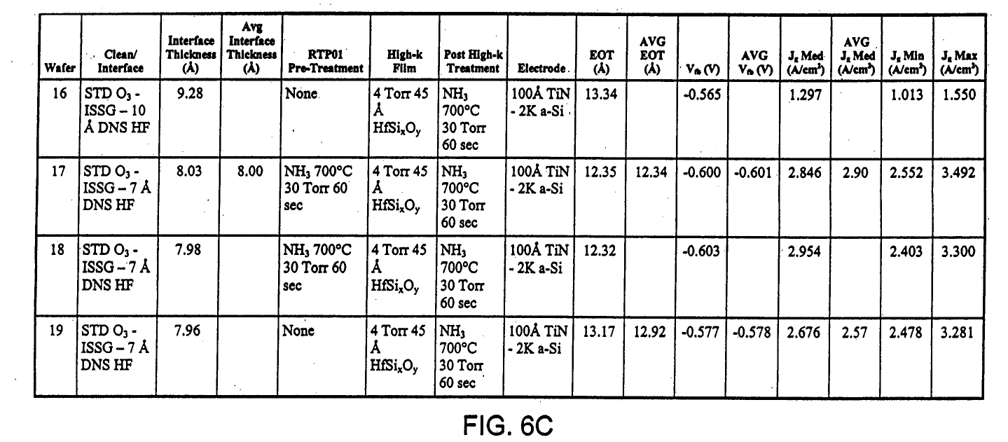

The recipe, shown in Table 1, was run as a baseline since it was known to be the best process at the time. The HF/HCl etch portion in Step 2 had used a 200:1:0.4 DI:HF:HCl formula at 23° C. and was targeted to remove 200 Å of thermal oxide. The O₃ was dispensed for 10 min at 23° C. with an O₃ concentration of 20 ppm and an HCl concentration of 0.2% as shown in Step 5 of Table 1. Further, the O₃ was dispensed at a power setting of “6” which corresponds to a megasonic power of approximately 420 MHz. The wafers were then transferred to the LPD where they received a 3-minute DI water rinse and a low pressure IPA/hot N₂ dry. The process designated “STD O₃” in FIGS. 6-16.

TABLE 1
Recipe an IMEC type-clean

| | STEP | | | | | | | |
|---|---|---|---|---|---|---|---|---|
| | 1 | 2 | 3 | 4 | 5 | 6 | 7 | 8 |
| | TIME (seconds) | | | | | | | |
| | 60 | 120 | 628 | 120 | 600 | 35 | 270 | 30 |
| de-ionized water DIW | • | • | | • | | | • | • |
| DIW-1 | | | | | | | | |
| O3 | | | | | • | | | |
| NH₄OH | | | | | | | | |
| H₂O₂ | | | | | | | | |
| HF | | • | | | | | | |
| Lo-flow HCL | | • | | | • | | | |
| High-flow HCL | | | | | | | | |
| SH | | | | | | • | | |
| QDR | | | | | | • | | |
| DIP | | | • | | | | | |
| DSM | | | | | • | | | |
| DIW-H | | | | | | | | |
| DSM-PW | | | | | 6 | | | |

2. A Chemical Oxide Formed by an RCA-Type Clean Using an HF/HCl-SC1-SC2 Sequence with a Reduced SC1 Process Temperature and SC1 Reduced Concentration to 100:2:1

The recipe, as shown in Table 2, includes an HF/HCl etch portion with a 200:1:0.4 DI:HF:HCl formula at 23° C. and was targeted to remove 200 Å of thermal oxide. The SC1 dispense used a 100:2:1 (H₂O:H₂O₂:NH₄OH) formula and was run at 23° for 7 minutes, as shown in Steps 2-3. The temperature of the 23° C. process was reached by dispensing room temperature water into the tank. The SC2 dispense used a 50:1:1 (H₂O:H₂O₂:HCl) formula and was run at 23° C. for 7 minutes, as shown in Steps 8-9. After the post-SC2 rinse, the wafers were transferred to the LPD where they received a 3-minute DI water rinse and a low pressure IPA/hot N₂ dry. The process is designated “SC1-23C” in FIGS. 6-16.

TABLE 2
Recipe for an RCA-type clean

| | STEP | | | | | | | | | | |
|---|---|---|---|---|---|---|---|---|---|---|---|
| | 1 | 2 | 3 | 4 | 5 | 6 | 7 | 8 | 9 | 10 | 11 |
| | TIME (seconds) | | | | | | | | | | |
| | 120 | 120 | 420 | 35 | 420 | 30 | 60 | 120 | 420 | 35 | 420 |
| Deionized Water (DIW) | | | | | • | | • | • | | | • |
| H-DIW (hi flow vs. lo flow | • | • | | | | | | | | | |
| O3 | | | | | | | | | | | |
| NH4OH | | • | | | | | | | | | |
| H2O2 | | • | | | | | | • | | | |
| HF | | | | | | | | | | | |
| HCL-1 (lo) | | | | | | | | | | | |
| HCL-2 (high) | | | | | | | | • | | | |
| SH Shower - moist wafer | | | | • | | | | | | • | |
| QDR (quick dump rinse) | | | | • | | • | | | | • | |
| DIP sitting Time | | | • | | | | | | • | | |
| DSM (megasonic) | | | • | | | | | | • | | |
| DIW-H (hot water flow) | 1 | 1 | | | | | | | | | |
| DSM-PW | | | 6 | | | | | | 6 | | |

3. Two Different ISSG Oxide Interfaces were Created by Performing Controlled Etches of 21 Å ISSG Oxides using an HF/HCl Process

The wafers were initially cleaned with the recipe as shown in of Table 1. Next, each wafer received a 21 Å ISSG process on a RTP, which consisted of a 16-second exposure to 4950 sccm of O₂ and 50 sccm of H₂ at 950° C. and 5.8 Torr. The wafers were then processed again through the DNS using the LPD-XHF process to reduce the oxide thickness from 21 Å. The HF/HCl etch portion of the process used a 200:1:0.4 DI:HF:HCl formula at 23° C.; the etch times were varied to target ˜10 Å of remaining ISSG for one split and ˜7 Å for another. However, the resultant thicknesses were approximately 9 Å and 8 Å, respectively. The processes are designated “ISSG-9 Å” and “ISSG-8 Å” in FIGS. 6-16.

4. An ISSG Oxide Interface Created by Performing an Over Etch of a 21 Å ISSG Oxide using an Anhydrous HF Process

The wafers were initially cleaned with the recipe illustrated in Step 1 of Table 1. The HF/HCl etch portion in Step 2 had used a 200:1:0.4 DI:HF:HCl formula at 23° C. and was targeted to remove 200 Å of thermal oxide. The O₃ was dispensed for 10 min at 23° C. with an O₃ concentration of 20 ppm and an HCl concentration of 0.2% as shown in Step 5 of Table 1. Further, the O₃ was dispensed at a power setting of “6” which corresponds to a megasonic power of approximately 420 MHz. The wafers were then transferred to the LPD where they received a 3-minute DI water rinse and a low pressure IPA/hot N₂ dry. The process designated “STD O₃” in FIGS. 6-16.

Each wafer subsequently received a 21 Å ISSG process on a RTP, which consisted of a 16-second exposure to 4950 sccm of O₂ and 50 sccm of H₂ at 950° C. and 5.8 Torr. The wafers were then processed through an anhydrous HF vapor process, as shown by the recipe shown in Table 3 which includes a rinse-etch-rinse process using anhydrous HF and water vapor targeted to remove 60 Å of thermal oxide. Before the vapor etch, a 5-second water rinse was employed to leave a uniform, adsorbed layer of moisture for better etch uniformity; after the vapor etch, a 7-second water rinse was employed to remove the etch residues. The clean left the wafer with a 3.7 Å (as measured using ellipsometry technique) partially hydrophobic, partially fluorine-terminated film on the wafer surface. This process is designated “ISSG-Anhy-NH₃” in FIGS. 6-16.

TABLE 3
Recipe for an Anhydrous HF Vapor Process

| | | | | | 301 pm | 10 lpm | 250 sccm | 500 sccm | 2 lpm | |
|---|---|---|---|---|---|---|---|---|---|---|
| Section | Step # | Step Name | Time Limits | Step Time | N2A [%] | Vapor [%] | HF1 [%] | HF2 [%] | N2b [%] | Rinse [0-9] |
| ETCH1 | 0 | High Purge | 4-60 | 5 | 90 | | | | 50 | |
| | 1 | Stabilize | 1-60 | 5 | 90 | | | | 50 | |
| | 2 | Pre-Treat | 0-60 | | | | | | | |
| | 3 | Etch | 0-60 | | | | | | | |
| | 4 | Etch | 0-60 | | | | | | | |
| | 5 | Shutdown | 0-60 | 1 | 20 | | | | 50 | |
| | 6 | High Purge | 0-60 | 1 | 20 | | | | 50 | 5 |
| Section | Step # | Step Name | Time Limits | Step Time | H2O [0/1] | N2a [%] | HF1 [%] | RPM | | |
| RINSE 1 | 0 | Rinse-Dry | 0-60 | 1 | 0 | 10 | | 100 | | |
| | 1 | Rinse-Dry | 0-60 | 4 | 1 | 10 | | 1000 | | |
| RCP 5 | 2 | Rinse-Dry | 0-60 | 1 | 0 | 10 | | 2000 | | |
| | 3 | Rinse-Dry | 0-60 | 10 | 0 | 100 | | 3000 | | |
| | 4 | Rinse-Dry | 0-60 | 1 | 0 | 100 | | 2000 | | |
| Section | Step # | Step Name | Time Limits | Step Time | N2A [%] | Vapor [%] | HF1 [%] | HF2 [%] | N2b [%] | Rinse [0-9] |
| ETCH2 | 7 | Stabilize | 0-60 | 1 | 40 | | | | 50 | |
| | 8 | Pre-Treat | 0-60 | 9 | 15 | 100 | | | 50 | |
| | 9 | Etch | 0-60 | 6 | 13 | 100 | 60.50 cc | | 50 | |
| | | | | | | | or 24% | | | |
| | 10 | Etch | 0-60 | 15 | 80 | 20 | | | 50 | |
| | 11 | Shutdown | 0-60 | 1 | 20 | | | | 50 | |
| | 12 | High Purge | 0-60 | 1 | 20 | | | | 50 | 7 |
| Section | Step # | Step Name | Time Limits | Step Time | H2O [0/1] | N2a [%] | HF1 [%] | RPM | | |
| RINSE 2 | 0 | Rinse-Dry | 0-60 | 1 | 0 | 10 | 0 | 100 | | |
| | 1 | Rinse-Dry | 0-60 | 3 | 1 | 10 | 0 | 1500 | | |
| RCP 7 | 2 | Rinse-Dry | 0-60 | 4 | 1 | 10 | 0 | 1000 | | |
| | 3 | Rinse-Dry | 0-60 | 1 | 0 | 80 | 0 | 1000 | | |
| | 4 | Rinse-Dry | 0-60 | 1 | 0 | 80 | 0 | 2000 | | |
| | 5 | Rinse-Dry | 0-60 | 10 | 0 | 80 | 0 | 3000 | | |
| | 6 | Rinse-Dry | 0-60 | 1 | 0 | 80 | 0 | 2000 | | |
| Section | Step # | Step Name | Time Limits | Step Time | N2A [%] | Vapor [%] | HF1 [%] | HF2 [%] | N2b [%] | Rinse [0-9] |
| ETCH3 | 13 | Stabilize | 0-60 | 1 | 100 | | | | 50 | |
| | 14 | Pre-Treat | 0-60 | | | | | | | |
| | 15 | Etch | 0-60 | | | | | | | |
| | 16 | Etch | 0-60 | | | | | | | |
| | 17 | Etch | 0-60 | | | | | | | |
| | 18 | Shutdown | 0-60 | | | | | | | |
| | 19 | High Purge | 0-60 | 10 | 100 | | | | 50 | |

Some wafers from the above oxide formations received an ammonia (NH₃) anneal at 700° C. and 30 Torr for 15 seconds and some did not. The pre-treated wafers are designated “NH₃-PreDA.” Those wafers that were not pre-treated are designated “-None.”

B. Semiconductor Wafer Preparation

The semiconductor wafers were staged immediately before pre-gate clean several weeks before their use. To ensure that queue time would not affect the results, all of the wafers underwent an SPM process before the actual pre-gate clean. The SPM was a 6:1 SPM:H₂O₂ process for 400 seconds at 130° C. followed by a series of dump-rinse cycles. The wafers were then transferred to the LPD where they received a 3-minute DI water rinse and a low pressure IPA/hot N₂ dry.

After the interfaces were formed, ellipsometer (AE) measurements were performed on an Optiprobe. The measurements consisted of a reliable single-wavelength HeNe laser source, polarizer, rotating compensator, and detector.

Next, a high-k deposition process consisted of an HfSiₓO_{y} film was deposited on all the wafers at 4 Torr, 485° C., and 45 Å. The wafers were then treated with a post high-k dielectric deposition. This was an NH₃ anneal at 700° C. and 30 Torr for 60 seconds. The deposition and post-treatment were completed as part of a sequenced recipe on a RTP.

A 100 Å TiSiN film was deposited in a chemical vapor deposition (CVD) system at 60 mTorr and 350° C. The gases used NH₃ and tetrakis (diethylamino) titanium (TDEAT). The deposition was followed immediately by a 10-second silane (SiH₄) soak to improve the integrity of the barrier layer.

A subsequent 1800 Å amorphous-silicon deposition process was performed in the RTP. The a-Si was deposited at 120 Torr and 620° C. using SiH₄ and H₂ for 128 seconds. For control and monitoring purposes, two wafers cleaned with the standard O₃ clean underwent the baseline ISSG process. These wafers are designated “ISSG” in the FIGS. 6-16. The 21 Å ISSG process on the RTP consisted of a 16-second exposure to 4950 sccm of O₂ and 50 sccm of H₂ at ° C. and 5.8 Torr. The wafers then underwent the TiN and a-Si processes described above.

C. Semiconductor Device Tests

1. Methodology

The wafers were automatically tested to collect electrical parameters. Many parameters were tested, but only those that had a high sensitivity to the effects of cleaning were selected such as transconductance, saturation current, threshold voltage, and leakage current. The data were collected on 17 die per wafer. On each die, transistors with a 10 μm gate width at gate lengths between 0.15 μm and 1.00 μm were measured. An additional 20 μm×20 μm capacitance pad was measured. For Gₘ, Vₜ, and I_{dsat} evaluation, the V_{dd} was set to 50 mV and Vₜ was obtained by linear extrapolation. For leakage current measurements, V_{g} was set equal to V_{dd} at a value of approximately 1.8 V. Further, constant voltage stress was measured with stress voltage set to 4.7 V. At the completion of the automated testing, C-V, I-V and I_{d}-V_{g} were measured manually.

The data from the test lab was entered and modeled to calculate EOT and V_{fb} values. Tₒₓ was calculated from C-V data using quantum corrections to the simple relationship Tₒₓ=εₒₓA/C where εₒₓ is the permittivity of SiO₂, A is the capacitor area, and C is the measured capacitance. The I-V data and the output from a model were then entered into a mobility model, which generated values for mobility, surface roughness, and interfacial state density.

Referring to FIGS. 6A-6C, a list of results of the oxide formed from the above embodiments and the respective EOT. Column 1 lists the 25 different wafers fabricated and tested. Column 2, entitled “Clean/Interface” refers to the cleaning and formation of the different types of oxide. Column 3, entitled “Interface Thickness (A)” refers to the thickness of the oxide after the etching and ammonia annealing process. Column 4, entitled “Avg. Interface Thickness (Å)” is an average thickness of all the wafers that have the same cleaning and formation process. Column 5, entitled “RTP01 Pre-Treatment” lists which wafer received the ammonia anneal process prior to the deposition of the high-k dielectric material deposition. Column 6, entitled “High-k Films” is the type and film deposited on the oxide layer. Column 7, entitled “Post High-k Treatment” is the ammonia anneal process done after the deposition of the high-k dielectric material. Column 8, entitled “Electrode” is the type of silicon substrate interface in which the oxide layer is formed. Column 9, entitled “EOT (Å)” is the equivalent oxide thickness for the respective semiconductor device on the wafer. Column 10, entitled “AVG EOT (Å)” is the average of the wafers in each experimental split (e.g. wafers 2, 3, 4 are one split, wafers 5, 6 are another split, etc.). Column 11-16 are electrical tests done on the transistors formed on the respective wafer.

2. Electrical Results

The EOT and V_{fb} data extracted from the CVC model are shown in FIGS. 6A-6C, column 9 and 11, respectively, along with their average by split. Also shown is the leakage current density data (column 13) at 1 V beyond V_{fb}. The median, maximum, and minimum data values encompass measurements at multiple sites.

3. EOT Data

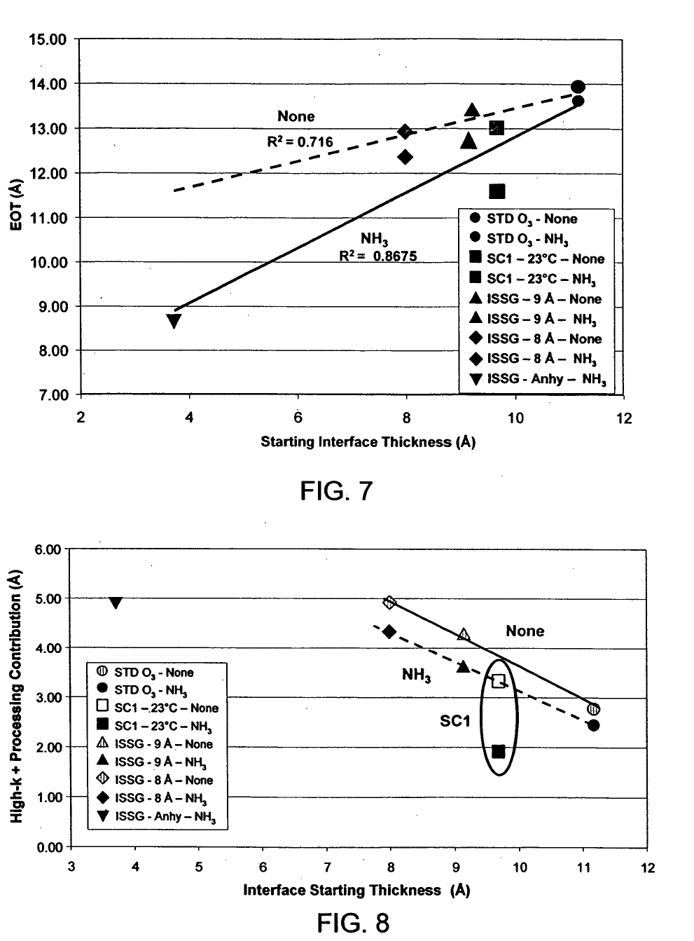

The results of the experiment were plotted as EOT vs. the starting interface thickness before any PreDA is shown in FIG. 7. The data show that the STD O₃ process started with the thickest interface and subsequently resulted in the highest EOTs. The thinnest starting interface corresponded to the ISSG-anhydrous HF sequence and resulted in the thinnest EOT (8.65 Å). The EOTs of the remaining splits had a direct correlation to the starting interface thicknesses but also corresponded to the PreDA. Those splits that received the NH₃ PreDA had an EOT 0.6 Å-1.4 Å less than similar splits without the PreDA.

To further illustrate the effect of the starting interface, the thickness of the starting interface was plotted against the contribution of the high-k and subsequent processing effects, calculated for each split as interface thickness subtracted from the EOT, as shown in FIG. 8. Since all wafers had the same 45 Å thick HfSiₓO_{y} film, subsequent processing after high-k deposition may have caused additional contributions due to growth or changes in composition of the interfacial oxide. The changes in the composition could possibly be caused by diffusion of the HfSiₓO_{y} into the interface. Based on these assumptions, it appears that the thicker the starting interfacial layer, the less additional growth or fewer compositional changes. Additionally, it appears that the NH₃ pre-treatment helped suppress additional changes; the thinner the initial interface, the greater the suppression.

4. EOT and Leakage

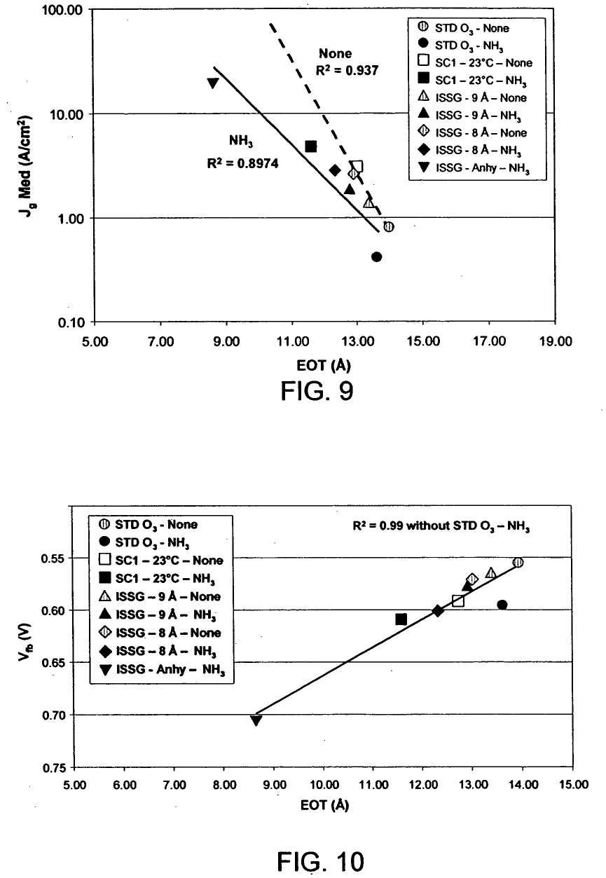

FIG. 9 illustrates EOT vs. leakage current density, J_{g}. Particularly, the graph shows two linear relationships: one for wafers pre-treated with NH₃ and one for those that had not been pre-treated. In both cases, as the EOT decreased, the leakage increased. The leakage current density trend of NH₃ PreDA wafers was less than that of the non-PreDA wafers, suggesting that the NH₃ PreDA reduced leakage. The goodness-of-fit numbers (R²) show a good fit of the data to the trends.

5. V_{fb} Results

A plot of V_{fb} vs. EOT is shown in FIG. 10 where a linear dependence on EOT, except for the STD O₃—NH₃ process sequence, which showed a significantly lower V_{fb} is illustrated. In general, the graph suggests that neither the clean nor the NH₃ PreDA significantly affected the V_{fb} except for the O₃ chemical oxide.

6. Transconductance, Saturation Current, and Threshold Voltage

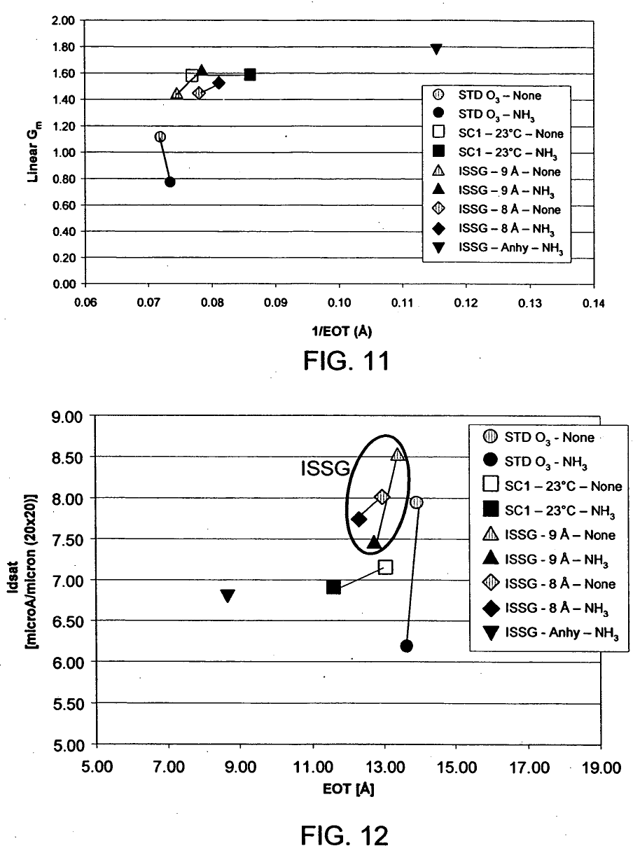

A plot of linear transconductance from a 20 μm×20 μm device vs. the inverse of the EOT (shown as 1/EOT) is shown in FIG. 11. The plot shows that for all but one split the transconductance increased or stayed constant when EOT decreased. These changes corresponded to the use of the NH₃ PreDA and were consistent with expected changes in the EOT. However, the same trends were not observed with the O₃ chemical oxide. The NH₃ degraded Gₘ on the O₃ chemical oxide.

A plot of saturation current from a 20 μm×20 μm device vs. EOT is shown in FIG. 12. For each split, NH₃ (which leads to thinner interfacial layer) decreases I_{dsat} Two additional observations can be seen from the plot. First, NH₃ appears to have a deleterious effect on the O₃ chemical oxide, causing a significant decrease in I_{dsat} with just a small change in EOT. The ISSG interfaces also had higher I_{dsat} values than the chemical oxides with similar or larger EOTs. Since ISSG oxides are thermally grown and denser than the chemical oxides, this result was not unexpected.

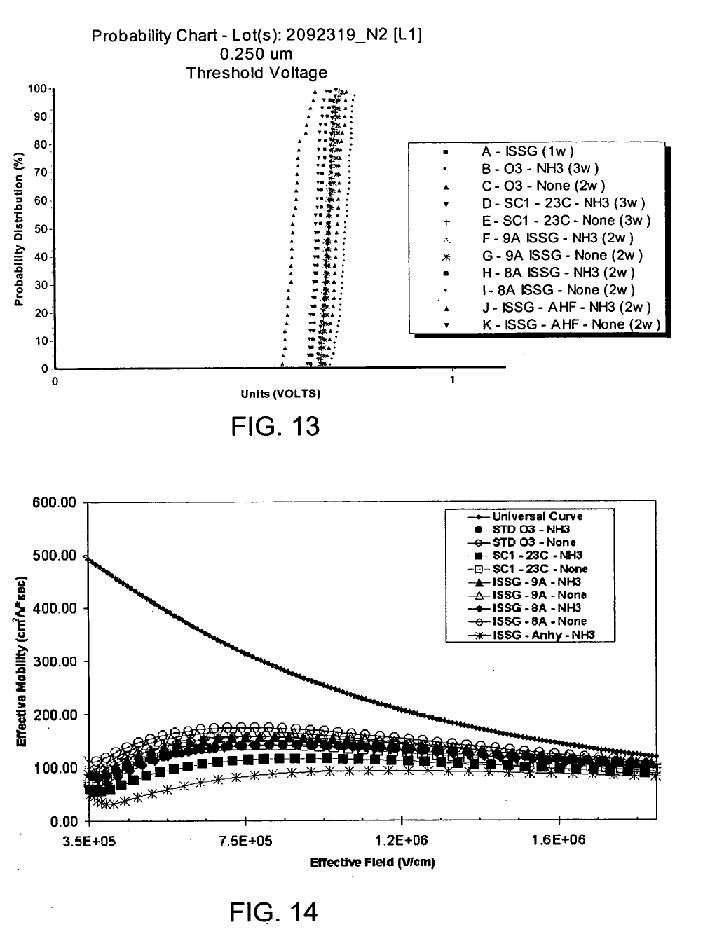

The Vₜ results in FIG. 13 show that Vₜ was uniform across the wafer and that the NH₃ PreDA had no significant effect, except for those differences caused by changes in EOT.

7. Results from the Mobility Test

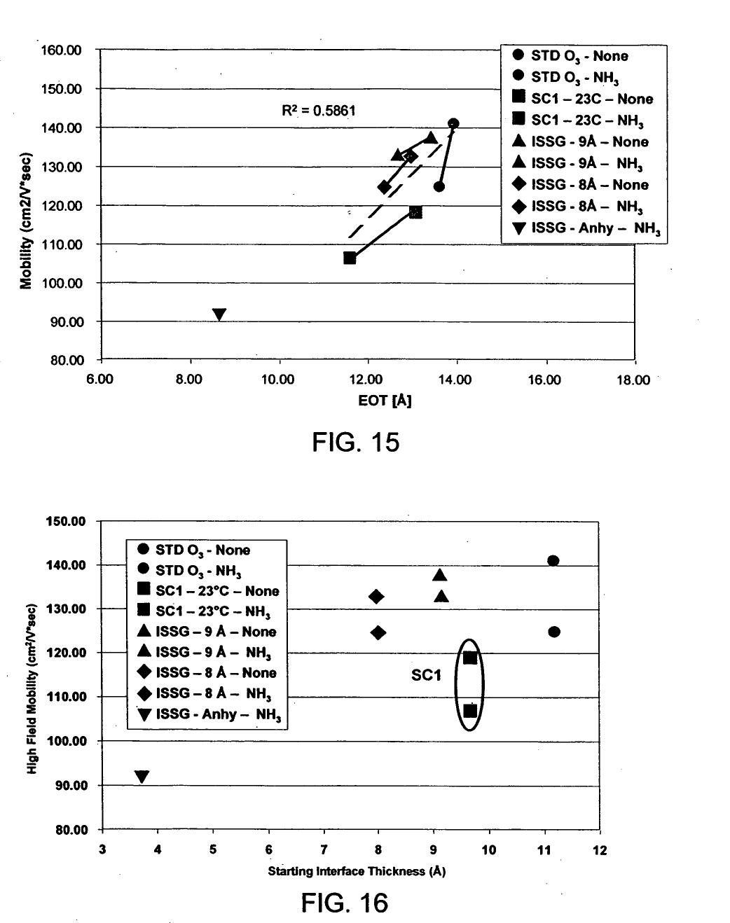

FIG. 14 shows the effective mobility curves generated from a mobility model for each split. The mobilities were all low, as had been seen with all high-k films studied to date. For high-k films, the data point of interest was the mobility at a high field value of 1.3E+6 V/cm. To differentiate between the clean/pre-treatment splits of interest, the median value of each split was plotted against the EOT. The resultant graph, FIG. 15 shows that the high field mobility values reduced as EOT reduced.

The thinner interfacial layer resulting from the NH₃ process may have been one contributor to the deleterious effect on mobility. The NH₃ also appears to have had a direct effect on mobility of O₃ chemical oxide, as the mobility fell significantly on O₃ wafers subjected to the NH₃ PreDA.

For similar EOTs, the mobilities appeared to be higher on wafers with ISSG interfaces than on those with chemical oxides. This was similar to the behavior observed with the I_{dsat} results. An additional graph showing the effect of the starting interface thickness vs. mobility is in FIG. 16. From this graph, several distinct trends can be seen. The NH₃ leads to thinner interfacial layer and thinner EOT, which appears to contribute to lower mobility. The NH₃ also appears have a direct effect on mobility of O₃ chemical oxide compared to the thinner ISSG oxides. Additionally, the SC1-SC2 chemical oxide has a deleterious effect on mobility.

D. Results

Additional growth or changes in the interface composition seem to have occurred with thinner starting interfacial layers. The NH₃ pre-treatment reduces EOTs where the thinner the initial interface, the greater the suppression or change. The SC1 chemical oxides behave differently than the O₃ chemical and ISSG thermal oxides. In general, the SC1-SC2 interface resulted in fewer additional changes and was more suppressed by NH₃. As the EOT decreased, leakage increased. The leakage current density trend suggested that the NH₃ PreDA reduced leakage.

Transconductance increased or stayed constant when EOT decreased, corresponding to the use of the NH₃. However, the NH₃ PreDA degraded Gₘ on the O₃ chemical oxide. The NH₃ PreDA on O₃ chemical oxide also appeared to significantly decrease I_{dsat} with just a small change in EOT. I_{dsat} was higher with the ISSG interfaces than on chemical oxides with similar or larger EOTs.

The NH₃ PreDA leads to thinner interfacial layer and thinner EOTs, which appeared to contribute to lower mobility. The NH₃ also appears to negatively impact the mobility of devices formed with O₃ chemical oxides. For similar EOTs, the mobilities appeared to be higher on wafers with ISSG interfaces than those with chemical oxides. Finally, the data indicate that the SC1-SC2 chemical oxide has a deleterious effect on mobility.

A NH₃ pre-treatment reduces EOTs by suppressing additional oxide growth or by changing the interface composition. The NH₃ PreDA leads to thinner interfacial layers and thinner EOTs, which appeared to contribute to reduced leakage but lower mobility. The NH₃ PreDA degraded Gₘ, I_{dsat}, and mobility on the O₃ chemical oxide compared to the scaled ISSG oxides. The SC1 chemical oxides appear to behave differently than the O₃ and ISSG interfaces and had a largely negative impact on mobility. As such, the ISSG interfaces scaled appropriately and had better overall electrical performance compared to the chemical oxide interfaces.

With the benefit of the present disclosure, those having skill in the art will comprehend that techniques claimed herein may be modified and applied to a number of additional, different applications, achieving the same or a similar result. The claims attached hereto cover all such modifications that fall within the scope and spirit of this disclosure.

The terms a or an, as used herein, are defined as one or more than one. The term plurality, as used herein, is defined as two or more than two. The term coupled, as used herein, is defined as connected, although not necessarily directly, and not necessarily mechanically. The term approximately, as used herein, is defined as at least close to a given value (e.g., preferably within 10% of, more preferably within 1% of, and most preferably within 0.1% of).

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. A semiconductor wafer comprising:
a silicon substrate;
an oxide layer coupled to the silicon substrate, the oxide layer being formed from an in situ steam generation process and etched back to a thickness of less than 10 Angstrom;
a high-k dielectric material coupled to the oxide layer.

19. The semiconductor wafer of claim 18, the oxide layer having a thickness of less than approximately 4 Angstroms.

20. The semiconductor wafer of claim 18, the high-k dielectric material having a thickness of approximately 45 Angstroms.

21. A semiconductor wafer comprising:
a silicon substrate;
an oxide layer coupled to the silicon substrate, the oxide layer formed from an in situ steam generation process and etched back to a thickness of less than 4 Angstrom;
a high-k dielectric material coupled to the oxide layer.

22. The semiconductor wafer of claim 21, the oxide layer having a thickness of less than 3.7 Angstroms.
